(19) United States
(12) Patent Application Publication
(10) Pub. No.: US 2025/0210519 A1
(43) Pub. Date: Jun. 26, 2025

(54) GATE-ALL-AROUND AND FORKSHEET DEVICE ARCHITECTURE IN STANDARD CELLS

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/390,887

(22) Filed: Dec. 20, 2023

(51) Int. Cl. H01L 23/528; H01L 21/768; H01L 29/40; H01L 29/417

(52) U.S. Cl. CPC H01L 23/5286; H01L 21/768; H10D 64/01; H10D 64/254

(57) ABSTRACT

Disclosed are semiconductor cells with side vertical contacts (SVCs) in contact with epitaxial source/drains (S/Ds). The SVCs increase the silicide contact area in between middle-of-line (MOL) contacts and the S/Ds. This can significantly reduce contact resistance at the silicide interface, which in turn can reduce the overall parasitic resistance of the cell.

### BACKGROUND OF THE DISCLOSURE

### 1. Field of the Disclosure

This disclosure relates generally to semiconductor devices, and more specifically, but not exclusively, to side vertical contacts (SVC) in semiconductor devices, such as forksheet (FS) and gate-all-around (GAA) devices. In an example application, the source/drain contact resistances can be significantly reduced with the proposed SVCs. This can be very useful in frontside and/or backside power distribution networks (FSPDN, BSPDN).

### 2. Description of the Related Art

Integrated circuit technology has achieved great strides in advancing computing power through miniaturization components such as semiconductor transistors. The progression of semiconductors has progressed from bulk substrates and planar CMOS, FinFETs, nanowires or nanoribbons (also called nanosheets), to nanowire or nanoribbon 3D stacking. The semiconductor technologies have largely been based on silicon. However, fabrication of transistors based on silicon may be problematic when it comes to further reduction in scaling, e.g., to few nanometers. Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor cell is disclosed. The semiconductor cell may comprise a source/drain (S/D). The S/D may be epitaxial (EPI). The semiconductor cell may also comprise a frontside contact (FSC) or a backside contact (BSC) or both. The frontside contact, when present, may be in contact with an upper surface of the S/D. The backside contact, when present, may be in contact with a lower surface of the S/D. The semiconductor cell may further comprise a side vertical contact (SVC) in contact with a side surface of the S/D.

An exemplary method of fabricating a semiconductor cell is disclosed. The method may comprise forming a source/drain (S/D). The S/D may be epitaxial (EPI). The method may also comprise forming a frontside contact (FSC) or forming a backside contact (BSC) or both. The frontside contact, when present, may be in contact with an upper surface of the S/D. The backside contact, when present, may be in contact with a lower surface of the S/D. The method may further comprise forming a side vertical contact (SVC) in contact with a side surface of the S/D.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a conventional GAA semiconductor device prior to forming source/drain (S/D) EPI.

FIG. 2 illustrates conventional FS semiconductor device prior to forming S/D EPIs.

FIG. 3 is a top view of a conventional FS semiconductor cell.

FIG. 4A, 4B, 4C illustrate cross sections along the Y direction along EPI regions of the conventional FS semiconductor cell.

FIG. 5 illustrates a top view of a proposed semiconductor cell in accordance with one or more aspects of the disclosure.

FIG. 6A, 6B, 6C illustrate cross sectional views along the Y direction along EPI regions of the proposed semiconductor cell in accordance with one or more aspects of the disclosure.

FIG. 6D illustrates a cross sectional view of the proposed semiconductor cell along the Y direction along a gate in accordance with one or more aspects of the disclosure.

FIGS. 7-12 illustrate flow charts of example methods of fabricating a semiconductor cell in accordance with one or more aspects of the disclosure.

FIG. 13 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor cells and methods for fabricating the same. In an aspect, the semiconductor cell may comprise a source/drain (S/D). The S/D may be epitaxial (EPI). The semiconductor cell may also comprise a frontside contact (FSC) or a backside contact (BSC) or both. The frontside contact, when present, may be in contact with an upper surface of the S/D. The backside contact, when present, may be in contact with a lower surface of the S/D. The semiconductor cell may further comprise a side vertical contact (SVC) in contact with a side surface of the S/D.

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises.” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In semiconductor devices such as gate-all-around (GAA) and forksheet (FS) devices, parasitic resistance is dominated by contact resistance at the silicide interface. That is, the resistance at an interface between a contact and an EPI source/drain is the dominant source of the total parasitic resistance. For example, in advanced node logic field effect transistors (FETs), the silicide interface resistance can account for 70% or more of the parasitic resistance at the transistor level.

One problem is that the silicide interface resistance increases with scaling. As cell heights and gate pitches shrink, the area to form the contact also shrinks. Also, as the nanosheet count grows (e.g., in GAA and FS devices), the silicide interface resistance bottleneck gets worse.

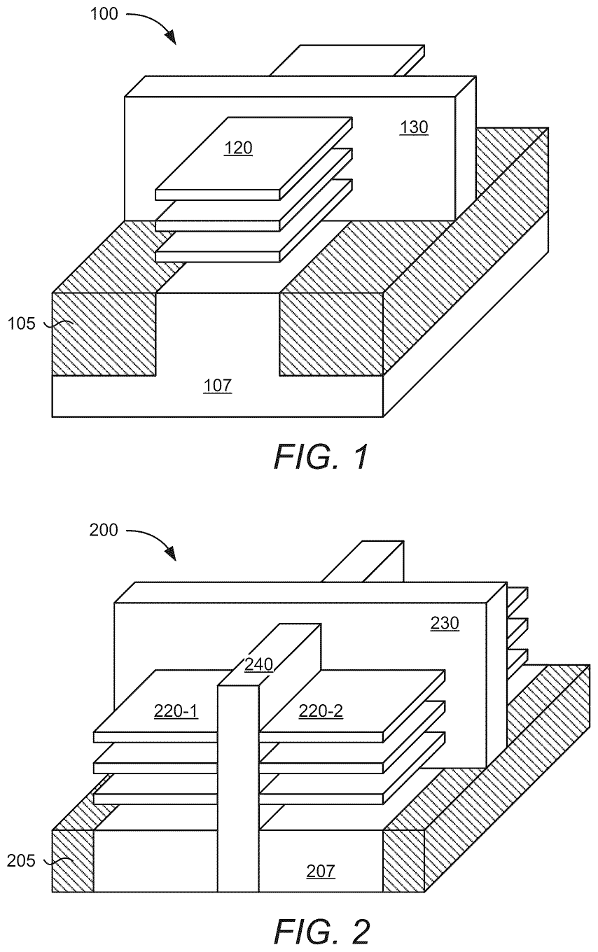

FIG. 1 illustrates a conventional semiconductor device—in this instance a conventional GAA semiconductor device 100—prior to forming source/drain (S/D) EPI. The conventional semiconductor device may illustrate a conventional GAA transistor structure. The GAA semiconductor device includes three nanosheets that extend through a gate 130 formed above a silicon (Si) substrate 107. Shallow trench isolations (STIs) 105 may be formed on outer (e.g., left and right) sides of the structure. The region of the nanosheets 120 adjacent to the gate 130 may be referred to as an EPI region.

The nanosheets 120 that extend from the channel areas (of the gate) will be recessed and/or etched off and EPI regions (not shown) will be grown from the nanosheets (or channel ribbons) later on in the process to form the transistor structure. However, the nanosheets 120 remain within the gate 130. The nanosheets 120 are the channels by which the charge carriers travel through the gate 130 from/to the S/D 150. It may be assumed that S/D is also formed on the rear side of the gate 130. Then one side (e.g., front) of the gate 130 may serve as the source and the other side (e.g., rear) of the gate 130 may serve as the drain.

FIG. 2 illustrates another conventional semiconductor device—in this instance a conventional FS semiconductor device-prior to forming the S/D EPIs. Forksheet (FS) architecture includes a dielectric wall (DW) between the N field effect transistor (NFET) and PFET. The dielectric wall enables space compaction by blocking epitaxial-to-epitaxial (EPI-to-EPI) shorting.

The FS semiconductor device 200 includes a dielectric wall (DW) 240 that completely separates a set of nanosheets into first and second nanosheets 220-1, 220-2. The first and second nanosheets 220-1, 220-2 extend through a gate 230 formed above a Si substrate 207. STIs 205 may be formed on outer (e.g., left and right) sides of the structure. The DW 240 splits the Si substrate 207 and also extends into the gate 230. The left and right regions occupied by the first and second nanosheets 220-1, 220-2 may be referred to as first and second EPI regions, which are separated by the DW 240. However, since the gate 230 is taller than the dielectric wall 240, the gate 230 itself is electrically continuous on both left and right of the dielectric wall 240.

Again, the nanosheets 220-1, 220-2 that extend from the channel areas (of the gate) will be recessed and/or etched off and EPI regions (not shown) will be grown from the nanosheets (or channel ribbons) later on in the process to form the transistor structure. In the first EPI region (i.e., region previously occupied by the first nanoheets 220-1), a first S/D 250-1 is formed. For example, the first S/D (e.g., one of N type and P type SD) is formed through epitaxial growth. In the second EPI region (i.e., region previously occupied by the second nanoheets 220-2), a second S/D 250-2 is formed. For example, the second S/D (e.g., other of N type and P type SD) is formed through epitaxial growth.

However, the nanosheets 220 remain within the gate 230. The nanosheets 220 are the channels by which the charge carriers travel through the gate 230 from/to the first and second S/Ds 250-1, 250-2. It may be assumed that first and second S/Ds are also formed on the rear side of the gate 230. In this instance, an inverter may be formed by the first and second S/Ds on both sides of the gate 230.

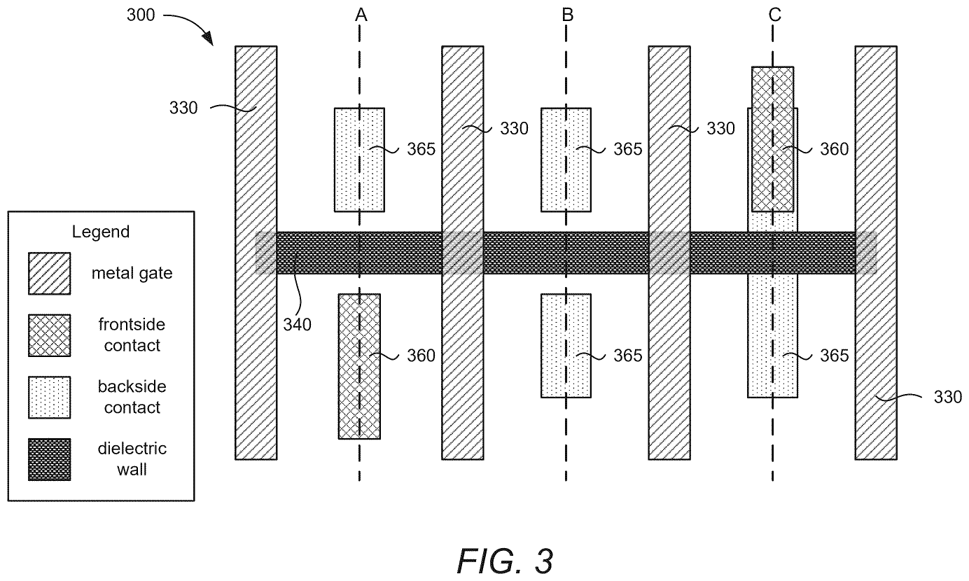

FIG. 3 is a top view of a conventional semiconductor device 300, in this instance a cell. The cell 300 is illustrated an FS semiconductor device (similar to semiconductor device 200) and includes metal gates 330 that run vertically. A dielectric wall (DW) 340 is horizontally placed and runs through the metal gates 330. Spaces in between the metal gates 330 are the EPI regions where epitaxial S/Ds are formed (not shown in FIG. 3). In the EPI regions, frontside contacts (FSCs) 360 and backside contacts (BSCs) 365 are formed, which can be electrically coupled with the first and second S/Ds.

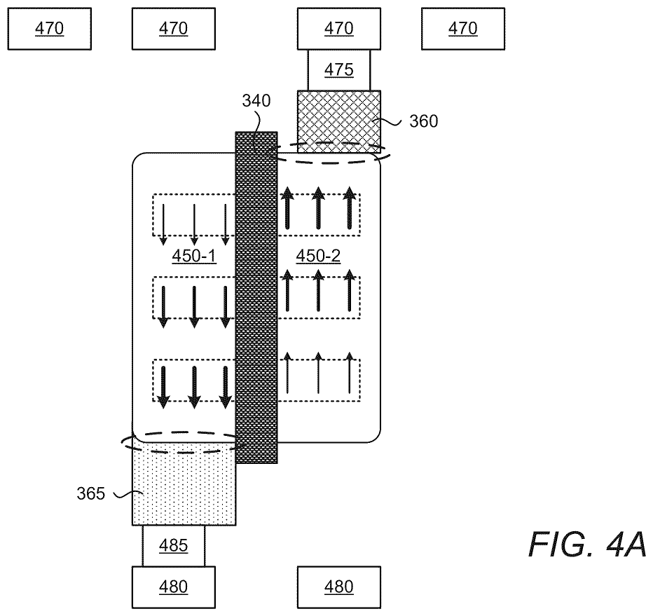

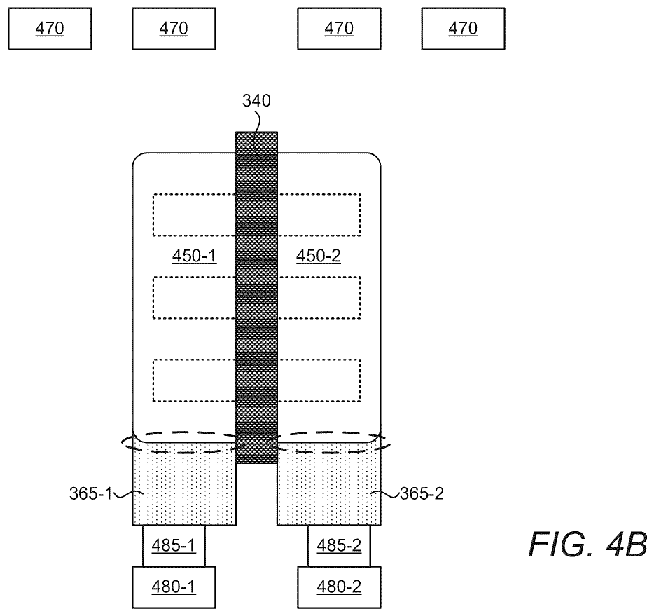

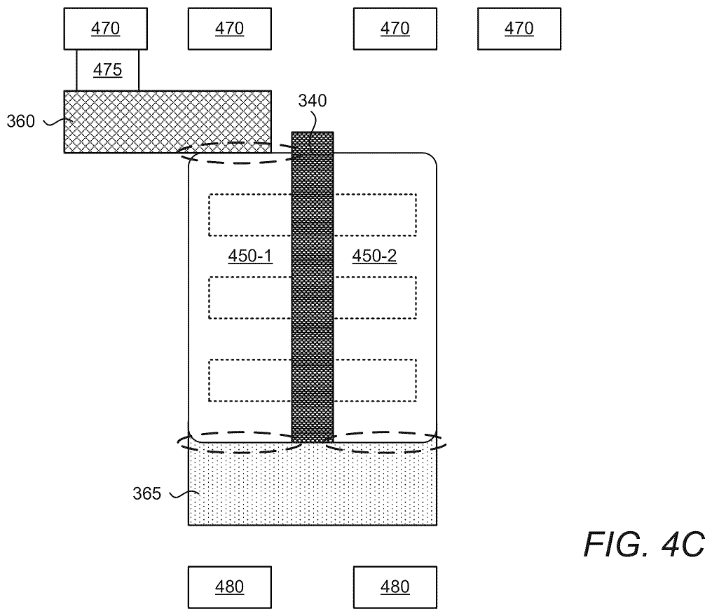

Note that in FIG. 3, there are three vertical lines labeled ‘A’, ‘B’ and ‘C’. FIG. 4A illustrates a cross section along the Y direction along the vertical line labeled ‘A’ of FIG. 3. This is a section of the cell 300 adjacent to the gate 330 where epitaxial S/Ds are formed. In FIG. 4A, a dielectric wall (DW) 440 splits the first (e.g., N) and second (e.g., P) S/Ds 450-1, 450-2 (similar to first and second S/Ds 250-1, 250-2 of FIG. 2). In FIG. 4A, areas previously occupied by the first and second nanosheets (such as nanosheets 220-1, 220-2)—prior to the formation of the first and second S/Ds 450-1, 450-2—are shown as dotted boxes. This is just to further illustrate that within the EPI regions, the nanosheets 220-1, 220-2 are removed when forming the first and second S/Ds 450-1, 450-2.

A backside (or bottom) contact 365 physically touches or interfaces with a lower lateral surface of the first S/D 450-1. Also, a backside metal (BM0) 485 is in contact with the backside contact 365, and a backside power/signal line 480 is in contact with the backside metal 485. In this way, the backside power/signal line 480 is electrically coupled with the first S/D 450-1 through the backside metal 485 and the backside contact 365.

A frontside (or top) contact 360 physically touches or interfaces with an upper lateral surface of the second S/D 450-2. Also, a frontside metal (FM0) 475 is in contact with the frontside contact 360, and a frontside power/signal line 470 is in contact with the frontside metal 475. In this way, the frontside power/signal line 470 is electrically coupled with the second S/D 450-2 through the frontside metal 475 and the frontside contact 360.

In FIG. 4A, arrows indicate the direction of current flow within the first and second S/Ds 450-1, 450-2. Also, the thicknesses of the arrows indicate amount of current flow. Note that at the interfaces between the first and second S/Ds 450-1, 450-2 and the backside and frontside contacts 365, 360, significant amount of current flows vertically, as indicated by the thicker arrows. That is, the sheet channels are out of phase behind the EPI regions, under the gate. For simplicity and to reduce clutter, the current flow indicating arrows are not depicted in FIGS. 4B and 4C.

FIG. 4B illustrates a cross section along the Y direction along the vertical line labeled ‘B’ of FIG. 3. This is another section of the cell 300 where epitaxial S/Ds are formed. The DW 440 splits the first (e.g., N) and second (e.g., P) S/Ds 450-1, 450-2. In this particular instance, a first backside contact 365-1 physically touches or interfaces with a lower lateral surface of the first S/D 450-1. A first backside metal 485-1 is in contact with the first backside contact 365-1, and a first backside power/signal line 480-1 is in contact with the first backside metal 485-1. In this way, the first backside power/signal line 480-1 is electrically coupled with the first S/D 450-1 through the first backside metal 485-1 and the first backside contact 365-1.

A second backside contact 365-2 physically touches or interfaces with a lower lateral surface of the second S/D 450-2. A second backside metal 485-2 is in contact with the second backside contact 365-2, and a second backside power/signal line 480-2 is in contact with the second backside metal 485-2. In this way, the second backside power/signal line 480-2 is electrically coupled with the second S/D 450-2 through the second backside metal 485-2 and the second backside contact 365-2.

FIG. 4C illustrates a cross section along the Y direction along the vertical line labeled ‘C’ of FIG. 3. This is yet another section of the cell 300 where epitaxial S/Ds are formed. The DW 440 splits the first (e.g., N) and second (e.g., P) S/Ds 450-1, 450-2. In this instance, a backside contact 365 physically touches or interfaces with lower lateral surfaces of both the first S/D 450-1 and the second S/D 450-2. A frontside contact 360 physically touches or interfaces with an upper lateral surface of the first S/D 450-1. Also, a frontside metal 475 is in contact with the frontside contact 360, and a frontside power/signal line 470 is in contact with the frontside metal 475. As seen, the frontside power/signal line 470 is electrically coupled with both the first and second S/Ds 450-1, 450-2 through the frontside metal 475, the frontside contact 360 and the backside contact 365.

In each of FIGS. 4A, 4B and 4C, there is a limited contact interface between the first and second S/Ds 450-1, 450-2 and the and top and/or bottom middle of line (MOL) contacts—namely the front side contact 360 and/or the back side contact 365. The contact interfaces are shown encompassed by dashed ovals. In FIGS. 4A, 4B and 4C, there are respectively two, two and three such contact interfaces.

There is a resistance penalty associated with such limited contact interface. First, all of the current goes through a small contact interface. Second, the current has to move vertically through the resistive epi, i.e., has to move through a small volume. As the ribbon count grows, this resistance problem will become worse.

To address this and other issues of conventional cells, it is proposed to use side vertical contacts (SVCs) to significantly increase the silicide contact area. The SVCs can work in both front and backside contact schemes. Also, SVC should not add to the cell height in any significant manner. Further, highly selective CVD TiSi processes can grow the silicide around all exposed epi areas.

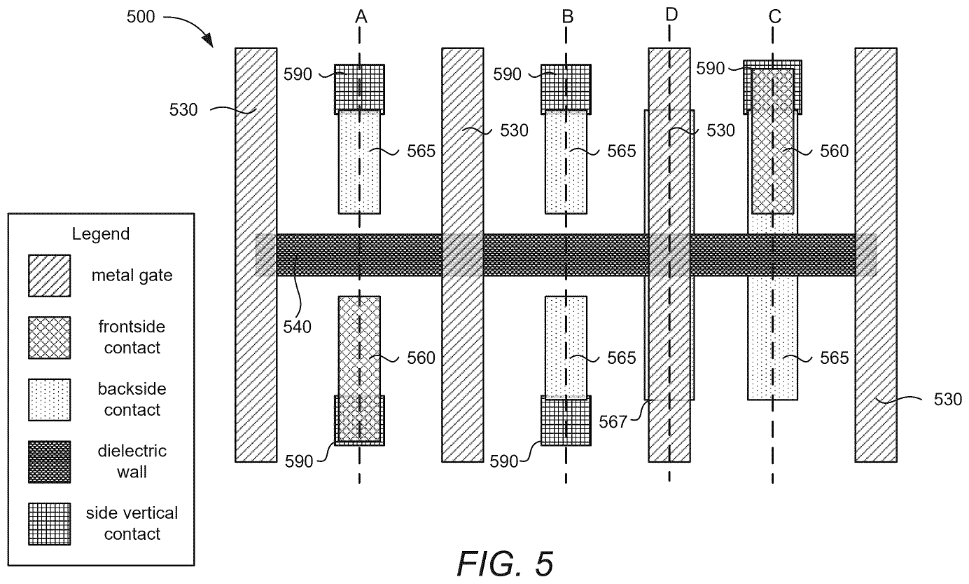

FIG. 5 is a top view of a proposed semiconductor device 500, in this instance a cell. In particular a forksheet (FS) cell 500 is illustrated. However, the concepts discussed may be applicable to any general gate-all-around (GAA) device scenario. The semiconductor cell 500 may include one or more gates 530 (e.g., metal gates) that run vertically. A dielectric wall (DW) 540 may be horizontally placed and may run through the gates 330. Spaces in between the gates 530 may be the EPI regions where epitaxial S/Ds are formed (not shown in FIG. 5). In the EPI regions, frontside contacts (FSCs) 560 and backside contacts (BSCs) 565 are formed, which can be electrically coupled with the first and second S/Ds. There may also be side vertical contacts (SVCs) 590 that are electrically coupled with the first and second S/Ds. For example, the SVCs 590 may be in physical contact with the first and second S/Ds. In some instances, the SVCs 590 may also be electrically coupled with (e.g., in physical contact with) the frontside and/or the backside contacts 560, 565.

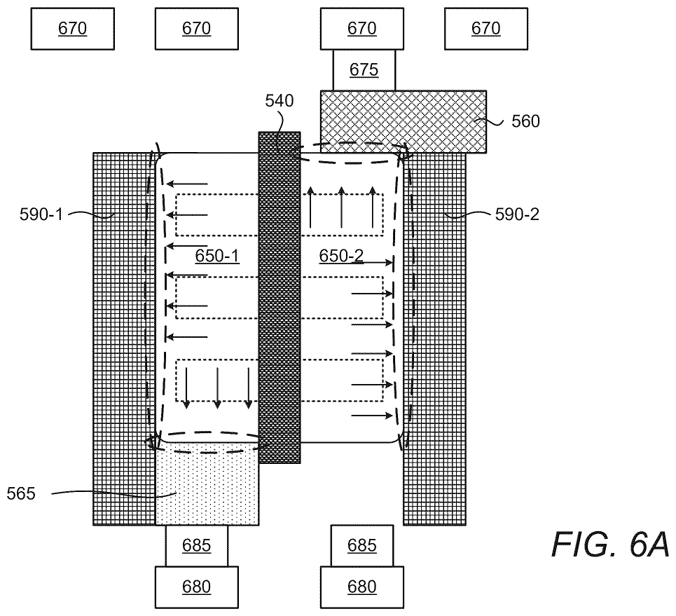

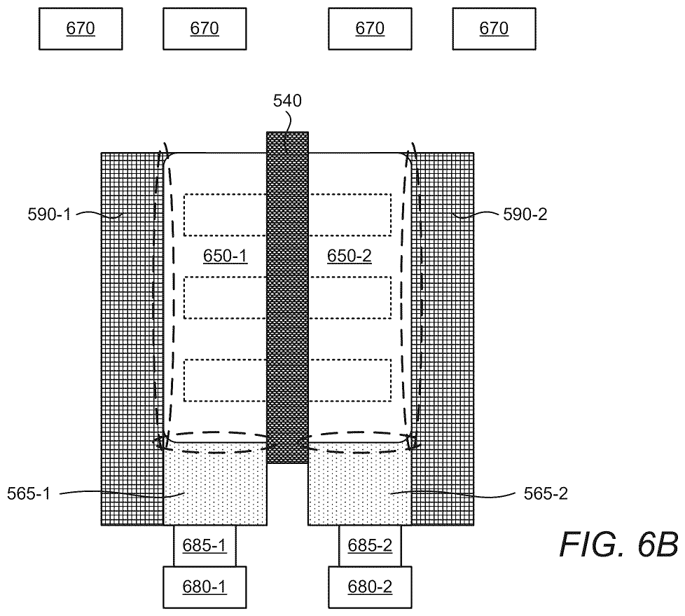

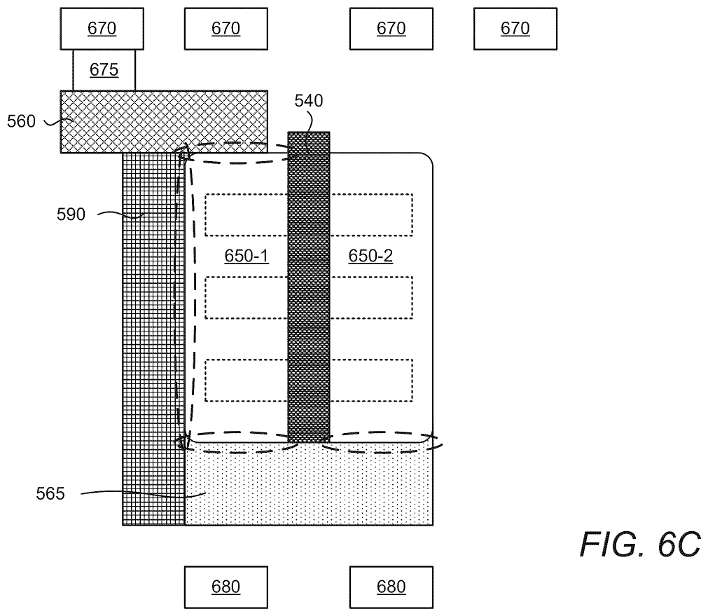

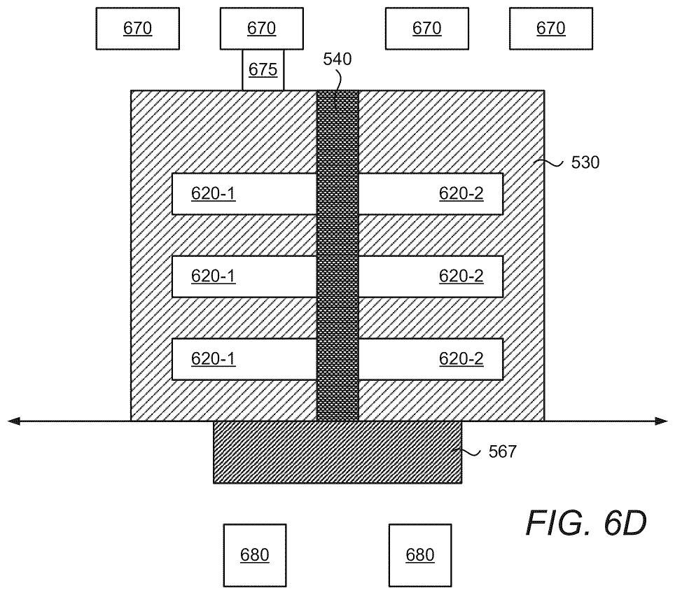

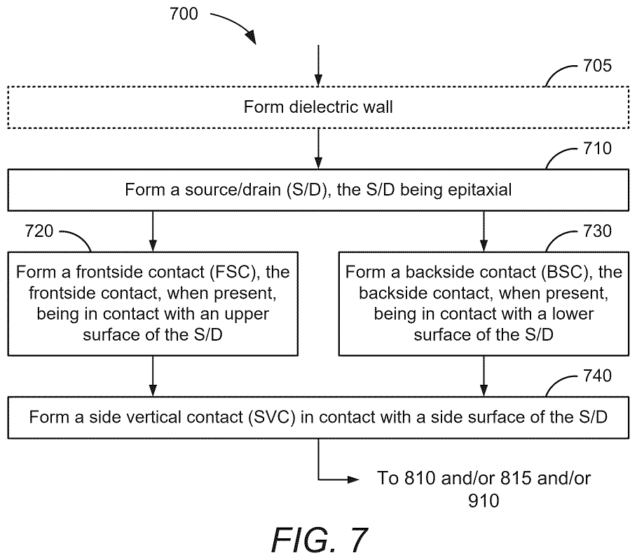

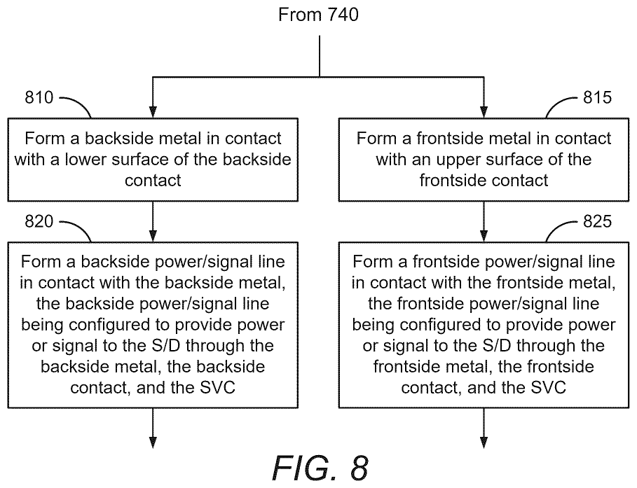

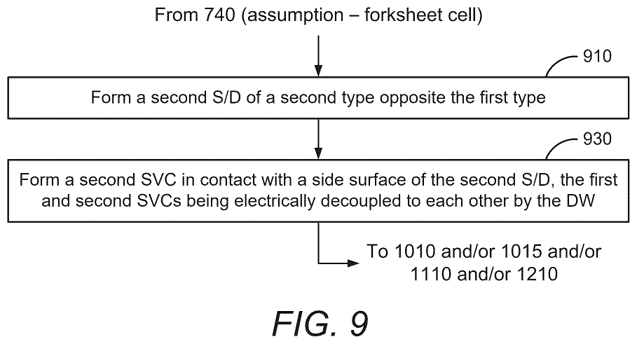

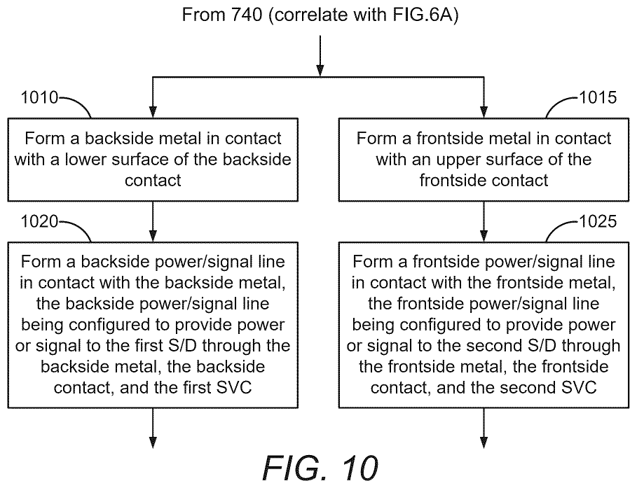

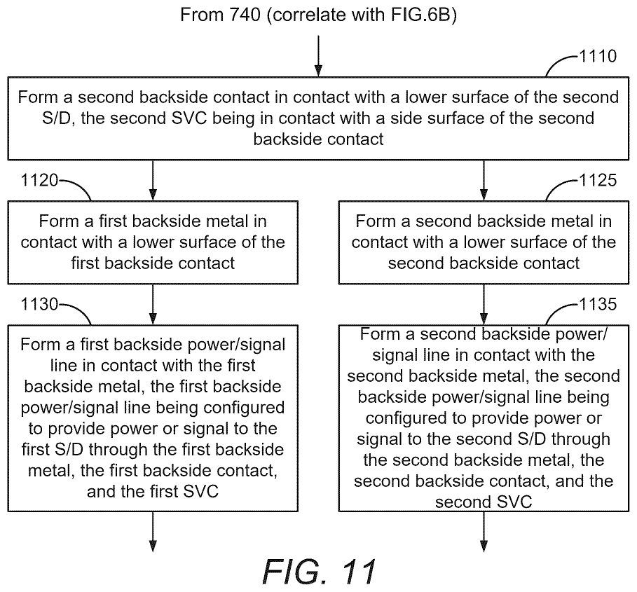

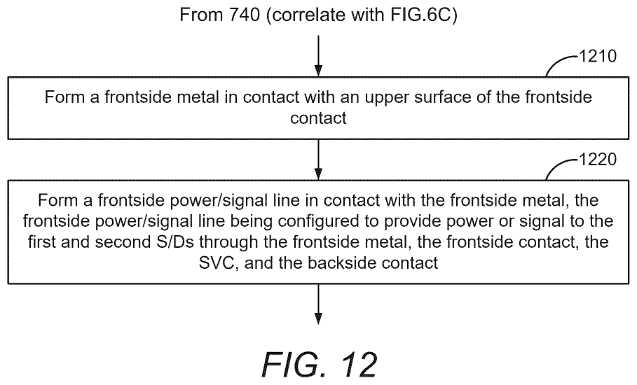

Note that in FIG. 5, there are three vertical lines labeled ‘A’, ‘B’, ‘C’ and ‘D’. FIG. 6A illustrates a cross section along the Y direction along the vertical line labeled ‘A’ of FIG. 5. This is a section of the cell 500 adjacent to the gate 530 where epitaxial S/Ds are formed. In FIG. 6A, a dielectric wall (DW) 640 splits the first (e.g., N) and second (e.g., P) S/Ds 650-1, 650-2, one or both of which may be epitaxial. In FIG. 6A, areas previously occupied by the first and second nanosheets (such as nanosheets 220-1, 220-2)—prior to the formation of the first and second S/Ds 650-1, 650-2—are shown as dotted boxes.

A backside (or bottom) contact 565 may physically touch or otherwise interface with a lower surface of the first S/D 650-1. More generally, the backside contact 565 may be electrically coupled with the lower surface of the first S/D 650-1. Also, a backside metal (BM0) 685 may be electrically coupled with (e.g., in contact with) the backside contact 565. A backside power/signal line 680 may be electrically coupled with (e.g., in contact with) the backside metal 685. In addition, a first SVC 590-1 may be electrically coupled with (e.g., in contact with) a side surface of the first S/D 650-1. In an aspect, the first SVC 590-1 may be in contact with an entirety of the side surface of the first S/D 650-1. In this way, the contact area may be maximized. The backside power/signal line 680 may be configured to provide power (e.g., Vdd, ground, etc.) or signal to the first S/D 650-1 through the backside metal 685, the backside contact 565, and the first SVC 590-1. The upper surface of the first S/D 650-1 and the upper surface of the first SVC 590-1 may be planar. Alternatively or in addition thereto, the lower surface of the first S/D 650-1 and the lower surface of the backside contact 565 may be planar.

A frontside (or top) contact 560 may physically touch or otherwise interface with an upper lateral surface of the second S/D 650-2. More generally, the frontside contact 560 may be electrically coupled with the upper surface of the second S/D 650-2. Also, a frontside metal (FM0) 675 may be electrically coupled with (e.g., in contact with) the frontside contact 560. A frontside power/signal line 670 may be electrically coupled with (e.g., is in contact with) the frontside metal 675. In addition, a second SVC 590-2 may be electrically coupled with (e.g., in contact with) a side surface of the second S/D 650-2. In an aspect, the second SVC 590-2 may be in contact with an entirety of the side surface of the second S/D 650-2. In this way, the contact area may be maximized. The frontside power/signal line 670 may be configured to provide power (e.g., Vdd, ground, etc.) or signal to the second S/D 650-2 through the frontside metal 675, the frontside contact 560, and the second SVC 590-2. The upper surface of the second S/D 650-2 and the upper surface of the second SVC 590-2 may be planar. In an aspect, lower surfaces of the first and second SVCs 590-1, 590-2 may be planar. Alternatively, or in addition thereto, upper surfaces of the first and second SVCs 590-1, 590-2 may be planar.

In FIG. 6A, arrows indicate the direction of current flow within the first and second S/Ds 650-1, 650-2. Also, the thicknesses of the arrows indicate amount of current flow. Note that due to the increase in interface surfaces afforded by the first and second SVCs 590-1, 590-2, the parasitic resistance can be significantly decreases (as indicated by the thin arrows). For simplicity and to reduce clutter, the current flow indicating arrows are not depicted in FIGS. 6B and 6C.

The concepts described herein may be applicable to GAA semiconductor cells in general including those with and without dielectric walls. For example, in a GAA semiconductor cell without a dielectric wall, this means that there may be a single S/D (either S/D 650-1 or 650-2—singularly referred to as S/D 650). In this instance, the semiconductor cell may include an S/D, which may be epitaxial.

The semiconductor cell may also include a frontside contact 560 or a backside contact 565 or both. If the frontside contact 560 is formed or otherwise present, the frontside contact 560 may be in contact with an upper surface of the S/D (e.g., in FIG. 6A, the frontside contact 560 is illustrated as being in contact with the upper surface of the S/D 650-2, and in FIG. 6C, the frontside contact 560 is illustrated as being in contact with the upper surface of the S/D 650-1). If the backside contact 565 is formed or otherwise present, the backside contact 565 may be in contact with a lower surface of the S/D (e.g., in FIGS. 6A and 6C, the backside contact 565 is illustrated as being in contact with the lower surface of the S/D 650-1, in FIG. 6B, a backside contact 565-1 is illustrated as being in contact with lower surface of the S/D 650-1).

A side vertical contact (SVC) 590 may be in contact with a side surface of the S/D 650 (e.g., in FIGS. 6A and 6B, the SVC 590-1 is illustrated as being in contact with the side surface of the S/D 650-1, and the SVC 590-2 is illustrated as being in contact with the side surface of the S/D 650-2). In an aspect, the SVC 590 may be in contact with an entirety of the side surface of the S/D 650. In another aspect, upper surfaces of the S/D 650 and of the SVC 590 may be planar.

When the backside contact 565 is present, the SVC 590 may be in contact with a side surface of the backside contact 565. Note that lower surfaces of the SVC 590 and the backside contact 565 may be planar. A backside metal 685 may be in contact with a lower surface of the backside contact 565. Also, a backside power/signal line 680 may be in contact with the backside metal 685. The backside power/signal line 680 may be configured to provide power or signal to the S/D 650 through the backside metal 685, the backside contact 565, and the SVC 590.

When the frontside contact 560 is present, the frontside contact 560 may be in contact with the upper surfaces of the S/D 650 and of the SVC 590. Note that upper surfaces of the SVC 590 and the frontside contact 560 may be planar. A frontside metal 675 may be in contact with the upper surface of the frontside contact 560. Also, a frontside power/signal line 670 may be in contact with the frontside metal 675. The frontside power/signal line 670 may be configured to provide power or signal to the S/D 650 through the frontside metal 675, the frontside contact 560, and the SVC 590.

FIG. 6B illustrates a cross section along the Y direction along the vertical line labeled ‘B’ of FIG. 5. This is another section of the cell 500 where epitaxial S/Ds are formed. The DW 640 splits the first (e.g., N) and second (e.g., P) S/Ds 650-1, 650-2, one or both of which may be epitaxial.

A first backside contact 565-1 may physically touch or otherwise interface with a lower surface of the first S/D 650-1. More generally, first backside contact 565-1 may be electrically coupled with the lower surface of the first S/D 650-1. Also, a first backside metal (BM0) 685-1 may be electrically coupled with (e.g., in contact with) the first backside contact 565-1. A first backside power/signal line 680-1 may be electrically coupled with (e.g., in contact with) the first backside metal 685-1. In addition, a first SVC 590-1 may be electrically coupled with (e.g., in contact with) a side surface of the first S/D 650-1. In an aspect, the first SVC 590-1 may be in contact with an entirety of the side surface of the first S/D 650-1. In this way, the contact area may be maximized. The first backside power/signal line 680-1 may be configured to provide power (e.g., Vdd, ground, etc.) or signal to the first S/D 650-1 through the first backside metal 685-1, the first backside contact 565-1, and the first SVC 590-1. The upper surface of the first S/D 650-1 and the upper surface of the first SVC 590-1 may be planar. Alternatively or in addition thereto, the lower surface of the first S/D 650-1 and the lower surface of the first backside contact 565-1 may be planar.

A second backside contact 565-2 may physically touch or otherwise interface with a lower surface of the second S/D 650-2. More generally, second backside contact 565-2 may be electrically coupled with the lower surface of the second S/D 650-2. Also, a second backside metal (BM0) 685-2 may be electrically coupled with (e.g., in contact with) the second backside contact 565-2. A second backside power/signal line 680-2 may be electrically coupled with (e.g., in contact with) the second backside metal 685-2. In addition, a second SVC 590-2 may be electrically coupled with (e.g., in contact with) a side surface of the second S/D 650-2. In an aspect, the second SVC 590-2 may be in contact with an entirety of the side surface of the second S/D 650-2. In this way, the contact area may be maximized. The second backside power/signal line 680-2 may be configured to provide power (e.g., Vdd, ground, etc.) or signal to the second S/D 650-2 through the second backside metal 685-2, the second backside contact 565-2, and the second SVC 590-2. The upper surface of the second S/D 650-2 and the upper surface of the second SVC 590-2 may be planar. Alternatively or in addition thereto, the lower surface of the second S/D 650-2 and the lower surface of the second backside contact 565-2 may be planar.

While not shown, it is contemplated that first and second frontside contacts 560-1, 560-2 may be formed instead of first and second backside contacts 565-1, 565-2. If the first and second frontside contacts 560-1, 560-2 are formed or otherwise provided, then there may be corresponding first and second frontside metals 675-1, 675-2 and first and second front side power/signal lines 670-1, 670-2.

In both FIGS. 6A and 6B, the first and second SVCs 590-1, 590-2 may be shaped similar. For example, upper surfaces of the first and second SVCs 590-1, 590-2 may be at a same upper height. Alternatively, or in addition thereto, lower surfaces of the first and second SVCs 590-1, 590-2 may be at a same lower height.

FIG. 6C illustrates a cross section along the Y direction along the vertical line labeled ‘C’ of FIG. 5. This is yet another section of the cell 500 where epitaxial S/Ds are formed. The DW 640 splits the first (e.g., N) and second (e.g., P) S/Ds 650-1, 650-2, one or both of which may be epitaxial.

In this instance, the backside contact 565 may be in contact with lower surfaces of the first and second S/Ds 650-1, 650-2, and the lower surface of the DW 540. This allows the first and second S/Ds 650-1, 650-2 to be electrically coupled to each other. In an aspect, the backside contact 565 may contact the entire lower surfaces of the first and second S/Ds 650-1, 650-2, and of the DW 540. The SVC 590 may be in contact with the side surface of the first S/D 650-1.

A frontside contact 560 may physically touch or otherwise interface with an upper lateral surface of the first S/D 650-1. Also, a frontside metal 675 may be electrically coupled with (e.g., in contact with) the frontside contact 560. A frontside power/signal line 670 may be electrically coupled with (e.g., is in contact with) the frontside metal 675. The frontside power/signal line 670 may be configured to provide power (e.g., Vdd, ground, etc.) or signal to the first and second S/Ds 650-1, 650-2 through the frontside metal 675, the frontside contact 560, the first SVC 590-1, and the backside contact 565.

While not shown, it is contemplated that a backside metal 685 may be formed to be in contact with the backside contact 565 and a backside power/signal line 680. This may be instead of or in addition to the frontside metal 675 and the frontside power/signal line 670. Also while not shown, it is contemplated that another SVC may be formed to be in contact with the side surface of the second S/D 650-2 and the backside contact 565 to maximize the contact area of the second S/D 650-2.

For completeness, FIG. 6D is provided to illustrate a cross section along the Y direction along the vertical line labeled ‘D’ of FIG. 5. FIG. 6D illustrates a gate 530 and a plurality of nanosheets within the gate 530. The DW 540 may split the gate 530 into first (e.g., left) and second (e.g., right) gate portions. The heights of the DW 540 and the gate 530 may be the same. For example, lower surfaces of the DW 540 and of the gate 530 may be planar. Alternatively, or in addition thereto, upper surfaces of the DW 540 and of the gate 530 may be planar.

The DW 440 may also split nanosheets into first and second nanosheets 620-1, 620-2. The first and second nanosheets 620-1, 620-2 may respectively form first and second channels when a turn-on signal or voltage is applied to the gate 530. When a turn-off signal or voltage is applied to the gate 530, the first and second channels may be prohibited from being formed.

The gate 530 may be shared by both the first and second nanosheets 620-1, 620-2 of the plurality of nanosheets. That is, the first and second shared gate portions may be electrically coupled with each other. This may be accomplished through a backside gate contact 567 formed on the backside of the gate 530. Note that the backside gate contact 567 may also be on the backside of the DW 440. The backside gate contact 567 may be in physical contact with the lower surface of the gate 530. In this way, the first and second shared gate portions of the shared gate 435 may be electrically coupled to each other through the backside gate contact 567. In an aspect, the backside gate contact 567 may be formed from same materials as the backside contact 565. Alternatively, they may be formed from different materials. Nonetheless, in an aspect, they may be formed from separate patterning steps. Hence, the backside gate 565 and the backside gate contact 567 may be treated separately.

A frontside metal 675 may be electrically coupled to (e.g., in contact with) the frontside of the gate 530. The frontside metal 675 may be configured to apply the turn-on and turn-off signals to the gate 530. One or more frontside power/signal lines 670 may be formed on the frontside of the gate 530 above the frontside metal 675. At least one frontside power/signal line 670 may be electrically coupled to (e.g., in contact with) an upper surface of the frontside metal 675. The at least one frontside power/signal line 670 may be configured to provide the turn-on and turn-off signals to the frontside metal 675.

While not shown, there can also be one or more backside power/signal lines 680 below the backside of the gate 530. For example, the one or more backside power/signal lines 680 may be formed below the backside contact 565.

FIG. 7 illustrates a flow chart of an example method 700 of fabricating a semiconductor cell, such as the cell 500 in accordance with one or more aspects of the disclosure. The flow chart of FIG. 7 may be applicable to generic GAA architectures—with or without the forksheet. In block 705, a dielectric wall 540 may be formed. Block 705 may be performed in the event forksheet is implemented. If a generic GAA architecture without the forksheet is implemented, then block 705 may be skipped. Hence, block 705 is shown as a dashed box to indicate it is optional (i.e., whether forksheet is implemented or not).

In block 710, a source/drain (S/D) 650 may be formed. The S/D 650 may be epitaxial.

One or both of blocks 720 and 730 may be performed. In block 720, a frontside contact (FSC) 560 may be formed. When present, the frontside contact 560 may be in contact with an upper surface of the S/D 650.

In block 730, a backside contact (BSC) 565 may be formed. When present, the backside contact 565 may be in in contact with a lower surface of the S/D 650.

In block 740, a side vertical contact (SVC) 590 may be formed. The SVC 590 may be in contact with a side surface of the S/D 650.

From block 740, the method may proceed to any one or more of blocks 810, 815 of FIG. 8 and 910 of FIG. 9.

The process illustrated in FIG. 8 may also be applicable to generic GAA architectures—with or without the forksheet. In block 810, a backside metal 685 may be formed. The backside metal 685 may be in contact with a lower surface of the backside contact 565.

In block 820, a backside power/signal line 680 may be formed to be in contact with the backside metal 685. The backside power/signal line 680 may be configured to provide power or signal to the S/D 650 through the backside metal 685, the backside contact 565, and the SVC 590.

Instead of or in addition to blocks 810 and 820, block 815 and 825 may be performed. In block 815, a frontside metal 675 may be formed. The frontside metal 675 may be in contact with an upper surface of the frontside contact 560.

In block 825, a frontside power/signal line 670 may be formed to be in contact with the frontside metal 675. The frontside power/signal line 670 may be configured to provide power or signal to the S/D 650 through the frontside metal 675, the frontside contact 560 and the SVC 590.

The process illustrated in FIG. 9 may be applicable to GAA architectures with forksheets. That is, block 705 has been performed. Here, it may be assumed that there are two S/Ds. Thus, in the process illustrated in FIG. 9, it may be assumed that the S/D 650 of FIG. 7 is a first S/D 650-1, which is of first type (e.g., one of N and P types). Consequently, it may also be assumed that the SVC 590 is in contact with the side surface of the first S/D 650-1 (e.g., see FIGS. 6A, 6B, 6C).

In block 910, a second S/D 650-2 may be formed. The second S/D 650-2 may be of a second type, which is opposite the first type. The dielectric wall 540 formed in block 705 may separate the first and second S/Ds 650-1, 650-2.

In block 930, a second SVC 590-2 may be formed. The second SVC 590-2 may be in contact with a side surface of the second S/D 650. The first and second SVCs 590-1, 590-2 may be electrically decoupled from each other by the DW 540.

From block 930, the method may proceed to any one or more of blocks 1010, 1015 of FIG. 10, block 1110 of FIG. 11, and block 1210 of FIG. 12.

The process illustrated in FIG. 10 may be applicable to the situation illustrated in FIG. 6A. In block 1010, a backside metal 685 may be formed. The backside metal 685 may be in contact with a lower surface of the backside contact 565.

In block 1020, a backside power/signal line 680 may be formed to be in contact with the backside metal 685. The backside power/signal line 680 may be configured to provide power or signal to the first S/D 650-1 through the backside metal 685, the backside contact 565 and the first SVC 590-1.

Instead of or in addition to blocks 1010 and 1020, block 1015 and 1025 may be performed. In block 1015, a frontside metal 675 may be formed. The frontside metal 675 may be in contact with an upper surface of the frontside contact 560.

In block 1025, a frontside power/signal line 670 may be formed to be in contact with the frontside metal 675. The frontside power/signal line 670 may be configured to provide power or signal to the second S/D 650-2 through the frontside metal 675, the frontside contact 560) and the second SVC 590-2.

The process illustrated in FIG. 11 may be applicable to the situation illustrated in FIG. 6B. In block 1110, a second backside contact 565-2 may be formed in contact with a lower surface of the second S/D 650-2. The second SVC 590-2 may be in contact with a side surface of the second backside contact 565-2.

In block 1120, a first backside metal 685-1 may be formed to be in contact with a lower surface of the first backside contact 565-1.

In block 1130, a first backside power/signal line 680-1 may be formed to be in contact with the first backside metal 685-1. The first backside power/signal line 680-1 may be configured to provide power or signal to the first S/D 650-1 through the first backside metal 685-1, the first backside contact 565-1 and the first SVC 590-1.

Instead of or in addition to blocks 1120 and 1130, block 1125 and 1135 may be performed. In block. 1125, a second backside metal 685-2 may be formed to be in contact with a lower surface of the second backside contact 565-2.

In block 1135, a second backside power/signal line 680-2 may be formed to be in contact with the second backside metal 685-2. The second backside power/signal line 680-2 may be configured to provide power or signal to the second S/D 650-2 through the second backside metal 685-2, the second backside contact 565-2 and the second SVC 590-2.

The process illustrated in FIG. 11 may be applicable to the situation illustrated in FIG. 6C. That is, the backside contact 565 may be in contact with lower surfaces of the first and second S/Ds 650-1, 650-2 and a lower surface of the DW 540. In block 1210, a frontside metal 675 may be formed to be in contact with an upper surface of the frontside contact 560.

In block 1220, a frontside power/signal line 670 may be formed to be in contact with the frontside metal 675. The frontside power/signal line 670 may be configured to provide power or signal to the first and second S/Ds 650-1, 650-2 through the frontside metal 675, the frontside contact 560, the SVC 590, and the backside contact 565.

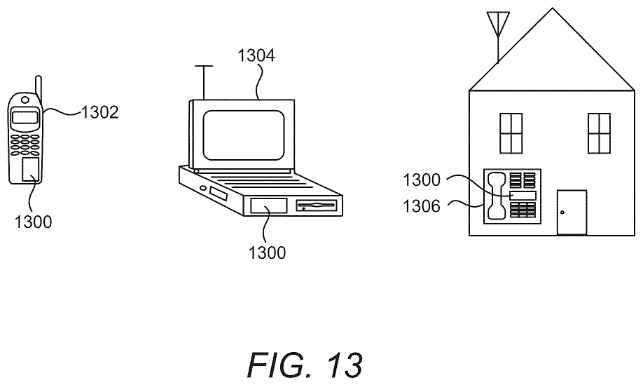

FIG. 13 illustrates various electronic devices 1300 that may be integrated with any of the aforementioned semiconductor devices in accordance with various aspects of the disclosure. For example, a mobile phone device 1302, a laptop computer device 1304, and a fixed location terminal device 1306 may each be considered generally user equipment (UE) and may include one or more cells (e.g., cells 500) as described herein. The devices 1302, 1304, 1306 illustrated in FIG. 13 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor cell, comprising: a source/drain (S/D), the S/D being epitaxial (EPI); a frontside contact (FSC) or a backside contact (BSC) or both, the frontside contact, when present, being in contact with an upper surface of the S/D, and the backside contact, when present, being in contact with a lower surface of the S/D; and a side vertical contact (SVC) in contact with a side surface of the S/D.

Clause 2: The semiconductor cell of clause 1, wherein the upper surface of the S/D and an upper surface of the SVC are planar.

Clause 3: The semiconductor cell of clauses 1-2, wherein the SVC is in contact with a side surface of the backside contact.

Clause 4: The semiconductor cell of clause 1-3, wherein the SVC is in contact with an entirety of the side surface of the S/D.

Clause 5: The semiconductor cell of clauses 1-4, wherein a lower surface of the backside contact and a lower surface of the SVC are planar.

Clause 6: The semiconductor cell of clauses 1-5, further comprising: a backside metal in contact with a lower surface of the backside contact; and a backside power/signal line in contact with the backside metal, the backside power/signal line being configured to provide power or signal to the S/D through the backside metal, the backside contact, and the SVC.

Clause 7: The semiconductor cell of clauses 1-6, wherein the frontside contact (FSC) in contact with an upper surface of the SVC.

Clause 8: The semiconductor cell of clause 7, further comprising: a frontside metal in contact with an upper surface of the frontside contact; and a frontside power/signal line in contact with the frontside metal, the frontside power/signal line being configured to provide power or signal to the S/D through the frontside metal, the frontside contact and the SVC.

Clause 9: The semiconductor cell of clauses 1-8, wherein the S/D is a first S/D of a first type, and the SVC is in contact with the side surface of the first S/D, and wherein the semiconductor cell further comprises: a second S/D of a second type opposite the first type; and a dielectric wall (DW) separating the first and second S/Ds.

Clause 10: The semiconductor cell of clause 9, wherein SVC is a first SVC in contact with the side surface of the first S/D, and wherein the semiconductor cell further comprises: a second SVC in contact with a side surface of the second S/D, the first and second SVCs being electrically decoupled to each other by the DW.

Clause 11: The semiconductor cell of clause 10, wherein an upper surface of the first SVC and an upper surface of the second SVC are at a same upper height, or wherein a lower surface of the first SVC and a lower surface of the second SVC are at a same lower height, or both.

Clause 12: The semiconductor cell of clauses 10-11, wherein the first SVC is in contact with a side surface of the backside contact, or wherein the frontside contact (FSC) in contact with an upper surface of the second SVC, or both.

Clause 13: The semiconductor cell of clause 12, further comprising: a backside metal in contact with a lower surface of the backside contact; and a backside power/signal line in contact with the backside metal, the backside power/signal line being configured to provide power or signal to the first S/D through the backside metal, the backside contact and the first SVC.

Clause 14: The semiconductor cell of clauses 12-13, further comprising: a frontside metal in contact with an upper surface of the frontside contact; and a frontside power/signal line in contact with the frontside metal, the frontside power/signal line being configured to provide power or signal to the second S/D through the frontside metal, the frontside contact and the second SVC.

Clause 15: The semiconductor cell of clauses 10-14, wherein the backside contact is a first backside contact, the first SVC being in contact with a side surface of the first backside contact, and wherein the semiconductor cell further comprises: a second backside contact in contact with a lower surface of the second S/D, the second SVC being in contact with a side surface of the second backside contact.

Clause 16: The semiconductor cell of clause 15, wherein semiconductor cell further comprises: a first backside metal in contact with a lower surface of the first backside contact; and a first backside power/signal line in contact with the first backside metal, the first backside power/signal line being configured to provide power or signal to the first S/D through the first backside metal, the first backside contact and the first SVC, or wherein semiconductor cell further comprises: a second backside metal in contact with a lower surface of the second backside contact; and a second backside power/signal line in contact with the second backside metal, the second backside power/signal line being configured to provide power or signal to the second S/D through the second backside metal, the second backside contact and the second SVC, or both.

Clause 17: The semiconductor cell of clauses 9-16, wherein the backside contact is in contact with lower surfaces of the first and second S/Ds and a lower surface of the DW.

Clause 18: The semiconductor cell of clause 17, wherein the frontside contact is in contact with upper surfaces of the first S/D and the SVC, and wherein the semiconductor cell further comprises: a frontside metal in contact with an upper surface of the frontside contact; and a frontside power/signal line in contact with the frontside metal, the frontside power/signal line being configured to provide power or signal to the first and second S/Ds through the frontside metal, the frontside contact, the SVC, and the backside contact.

Clause 19: The semiconductor cell of clauses 17-18, wherein the backside contact is in contact with entireties of the lower surfaces of the first and second S/Ds and the lower surface of the DW.

Clause 20: The semiconductor cell of clauses 1-19, wherein the semiconductor cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 21: A method of fabricating a semiconductor cell, the method comprising: forming a source/drain (S/D), the S/D being epitaxial (EPI); forming a frontside contact (FSC) or forming a backside contact (BSC) or both, the frontside contact, when present, being in contact with an upper surface of the S/D, and the backside contact, when present, being in contact with a lower surface of the S/D; and forming a side vertical contact (SVC) in contact with a side surface of the S/D.

Clause 22: The method of clause 21, wherein the upper surface of the S/D and an upper surface of the SVC are planar.

Clause 23: The method of clauses 21-22, wherein the SVC is in contact with a side surface of the backside contact.

Clause 24: The method of clause 21-23, wherein the SVC is in contact with an entirety of the side surface of the S/D.

Clause 25: The method of clauses 21-24, wherein a lower surface of the backside contact and a lower surface of the SVC are planar.

Clause 26: The method of clauses 21-25, further comprising: forming a backside metal in contact with a lower surface of the backside contact; and forming a backside power/signal line in contact with the backside metal, the backside power/signal line being configured to provide power or signal to the S/D through the backside metal, the backside contact, and the SVC.

Clause 27: The method of clauses 21-26, wherein the frontside contact (FSC) in contact with an upper surface of the SVC.

Clause 28: The method of clause 27, further comprising: forming a frontside metal in contact with an upper surface of the frontside contact; and forming a frontside power/signal line in contact with the frontside metal, the frontside power/signal line being configured to provide power or signal to the S/D through the frontside metal, the frontside contact and the SVC.

Clause 29: The method of clauses 21-28, wherein the S/D is a first S/D of a first type, and the SVC is in contact with the side surface of the first S/D, and wherein the method further comprises: forming a dielectric wall (DW) prior to forming the first S/D; and forming a second S/D of a second type opposite the first type, the dielectric wall (DW) separating the first and second S/Ds.

Clause 30: The method of clause 29, wherein SVC is a first SVC in contact with the side surface of the first S/D, and wherein the method further comprises: forming a second SVC in contact with a side surface of the second S/D, the first and second SVCs being electrically decoupled to each other by the DW.

Clause 31: The method of clause 30, wherein an upper surface of the first SVC and an upper surface of the second SVC are at a same upper height, or wherein a lower surface of the first SVC and a lower surface of the second SVC are at a same lower height, or both.

Clause 32: The method of clauses 30-31, wherein the first SVC is in contact with a side surface of the backside contact, or wherein the frontside contact (FSC) in contact with an upper surface of the second SVC, or both.

Clause 33: The method of clause 32, further comprising: forming a backside metal in contact with a lower surface of the backside contact; and forming a backside power/signal line in contact with the backside metal, the backside power/signal line being configured to provide power or signal to the first S/D through the backside metal, the backside contact and the first SVC.

Clause 34: The method of clauses 32-33, further comprising: forming a frontside metal in contact with an upper surface of the frontside contact; and forming a frontside power/signal line in contact with the frontside metal, the frontside power/signal line being configured to provide power or signal to the second S/D through the frontside metal, the frontside contact and the second SVC.

Clause 35: The method of clauses 30-34, wherein the backside contact is a first backside contact, the first SVC being in contact with a side surface of the first backside contact, and wherein the method further comprises: forming a second backside contact in contact with a lower surface of the second S/D, the second SVC being in contact with a side surface of the second backside contact.

Clause 36: The method of clause 35, wherein method further comprises: forming a first backside metal in contact with a lower surface of the first backside contact; and forming a first backside power/signal line in contact with the first backside metal, the first backside power/signal line being configured to provide power or signal to the first S/D through the first backside metal, the first backside contact and the first SVC, or wherein method further comprises: forming a second backside metal in contact with a lower surface of the second backside contact; and forming a second backside power/signal line in contact with the second backside metal, the second backside power/signal line being configured to provide power or signal to the second S/D through the second backside metal, the second backside contact and the second SVC, or both.

Clause 37: The method of clause 29-36, wherein the backside contact is in contact with lower surfaces of the first and second S/Ds and a lower surface of the DW.

Clause 38: The method of clause 37, wherein the frontside contact is in contact with upper surfaces of the first S/D and the SVC, and wherein the method further comprises: forming a frontside metal in contact with an upper surface of the frontside contact; and forming a frontside power/signal line in contact with the frontside metal, the frontside power/signal line being configured to provide power or signal to the first and second S/Ds through the frontside metal, the frontside contact, the SVC, and the backside contact.

Clause 39: The method of clauses 37-38, wherein the backside contact is in contact with entireties of the lower surfaces of the first and second S/Ds and the lower surface of the DW.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor cell, comprising:
a source/drain (S/D), the S/D being epitaxial (EPI);
a frontside contact (FSC) or a backside contact (BSC) or both, the frontside contact, when present, being in contact with an upper surface of the S/D, and the backside contact, when present, being in contact with a lower surface of the S/D; and
a side vertical contact (SVC) in contact with a side surface of the S/D.

2. The semiconductor cell of claim 1, wherein the upper surface of the S/D and an upper surface of the SVC are planar.

3. The semiconductor cell of claim 1, wherein the SVC is in contact with a side surface of the backside contact.

4. The semiconductor cell of claim 1, wherein the SVC is in contact with an entirety of the side surface of the S/D.

5. The semiconductor cell of claim 1, wherein a lower surface of the backside contact and a lower surface of the SVC are planar.

6. The semiconductor cell of claim 1, further comprising:
a backside metal in contact with a lower surface of the backside contact; and
a backside power/signal line in contact with the backside metal, the backside power/signal line being configured to provide power or signal to the S/D through the backside metal, the backside contact, and the SVC.

7. The semiconductor cell of claim 1, wherein the frontside contact (FSC) in contact with an upper surface of the SVC.

8. The semiconductor cell of claim 7, further comprising:
a frontside metal in contact with an upper surface of the frontside contact; and
a frontside power/signal line in contact with the frontside metal, the frontside power/signal line being configured to provide power or signal to the S/D through the frontside metal, the frontside contact and the SVC.

9. The semiconductor cell of claim 1,
wherein the S/D is a first S/D of a first type, and the SVC is in contact with the side surface of the first S/D, and
wherein the semiconductor cell further comprises:
a second S/D of a second type opposite the first type; and
a dielectric wall (DW) separating the first and second S/Ds.

10. The semiconductor cell of claim 9,
wherein SVC is a first SVC in contact with the side surface of the first S/D, and
wherein the semiconductor cell further comprises:
a second SVC in contact with a side surface of the second S/D, the first and second SVCs being electrically decoupled from each other by the DW.

11. The semiconductor cell of claim 10,
wherein an upper surface of the first SVC and an upper surface of the second SVC are at a same upper height, or
wherein a lower surface of the first SVC and a lower surface of the second SVC are at a same lower height, or
both.

12. The semiconductor cell of claim 10,
wherein the first SVC is in contact with a side surface of the backside contact, or
wherein the frontside contact (FSC) in contact with an upper surface of the second SVC, or
both.

13. The semiconductor cell of claim 12, further comprising:
a backside metal in contact with a lower surface of the backside contact; and
a backside power/signal line in contact with the backside metal, the backside power/signal line being configured to provide power or signal to the first S/D through the backside metal, the backside contact and the first SVC.

14. The semiconductor cell of claim 12, further comprising:
a frontside metal in contact with an upper surface of the frontside contact; and
a frontside power/signal line in contact with the frontside metal, the frontside power/signal line being configured to provide power or signal to the second S/D through the frontside metal, the frontside contact and the second SVC.

15. The semiconductor cell of claim 10,
wherein the backside contact is a first backside contact, the first SVC being in contact with a side surface of the first backside contact, and
wherein the semiconductor cell further comprises:
a second backside contact in contact with a lower surface of the second S/D, the second SVC being in contact with a side surface of the second backside contact.

16. The semiconductor cell of claim 15,
wherein semiconductor cell further comprises:
a first backside metal in contact with a lower surface of the first backside contact; and
a first backside power/signal line in contact with the first backside metal, the first backside power/signal line being configured to provide power or signal to the first S/D through the first backside metal, the first backside contact and the first SVC, or
wherein semiconductor cell further comprises:
a second backside metal in contact with a lower surface of the second backside contact; and
a second backside power/signal line in contact with the second backside metal, the second backside power/signal line being configured to provide power or signal to the second S/D through the second backside metal, the second backside contact and the second SVC, or
both.

17. The semiconductor cell of claim 9, wherein the backside contact is in contact with lower surfaces of the first and second S/Ds and a lower surface of the DW.

18. The semiconductor cell of claim 17,
wherein the frontside contact is in contact with upper surfaces of the first S/D and the SVC, and
wherein the semiconductor cell further comprises:
a frontside metal in contact with an upper surface of the frontside contact; and
a frontside power/signal line in contact with the frontside metal, the frontside power/signal line being configured to provide power or signal to the first and second S/Ds through the frontside metal, the frontside contact, the SVC, and the backside contact.

19. The semiconductor cell of claim 17, wherein the backside contact is in contact with entireties of the lower surfaces of the first and second S/Ds and the lower surface of the DW.

20. The semiconductor cell of claim 1, wherein the semiconductor cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

21. A method of fabricating a semiconductor cell, the method comprising:
forming a source/drain (S/D), the S/D being epitaxial (EPI);
forming a frontside contact (FSC) or forming a backside contact (BSC) or both, the frontside contact, when present, being in contact with an upper surface of the S/D, and the backside contact, when present, being in contact with a lower surface of the S/D; and
forming a side vertical contact (SVC) in contact with a side surface of the S/D.

22. The method of claim 21, further comprising:
forming a backside metal in contact with a lower surface of the backside contact; and
forming a backside power/signal line in contact with the backside metal, the backside power/signal line being configured to provide power or signal to the S/D through the backside metal, the backside contact, and the SVC.

23. The method of claim 21,
wherein the frontside contact (FSC) in contact with an upper surface of the SVC, and
wherein the method further comprises:
forming a frontside metal in contact with an upper surface of the frontside contact; and
forming a frontside power/signal line in contact with the frontside metal, the frontside power/signal line being configured to provide power or signal to the S/D through the frontside metal, the frontside contact and the SVC.

24. The method of claim 21,
wherein the S/D is a first S/D of a first type, and the SVC is in contact with the side surface of the first S/D, and
wherein the method further comprises:
forming a dielectric wall (DW) prior to forming the first S/D; and
forming a second S/D of a second type opposite the first type, the dielectric wall (DW) separating the first and second S/Ds.

25. The method of claim 24,
wherein SVC is a first SVC in contact with the side surface of the first S/D, and
wherein the method further comprises:
forming a second SVC in contact with a side surface of the second S/D, the first and second SVCs being electrically decoupled from each other by the DW.

26. The method of claim 25,
wherein the first SVC is in contact with a side surface of the backside contact, or
wherein the frontside contact (FSC) in contact with an upper surface of the second SVC, or
both, and
wherein the method further comprises:
forming a backside metal in contact with a lower surface of the backside contact; and
forming a backside power/signal line in contact with the backside metal, the backside power/signal line being configured to provide power or signal to the first S/D through the backside metal, the backside contact and the first SVC.

27. The method of claim 25, further comprising:
wherein the first SVC is in contact with a side surface of the backside contact, or
wherein the frontside contact (FSC) in contact with an upper surface of the second SVC, or
both, and
wherein the method further comprises:
forming a frontside metal in contact with an upper surface of the frontside contact; and
forming a frontside power/signal line in contact with the frontside metal, the frontside power/signal line being configured to provide power or signal to the second S/D through the frontside metal, the frontside contact and the second SVC.

28. The method of claim 25,
wherein the backside contact is a first backside contact, the first SVC being in contact with a side surface of the first backside contact, and
wherein the method further comprises:
forming a second backside contact in contact with a lower surface of the second S/D, the second SVC being in contact with a side surface of the second backside contact.

29. The method of claim 28,
wherein method further comprises:
forming a first backside metal in contact with a lower surface of the first backside contact; and
forming a first backside power/signal line in contact with the first backside metal, the first backside power/signal line being configured to provide power or signal to the first S/D through the first backside metal, the first backside contact and the first SVC, or
wherein method further comprises:
forming a second backside metal in contact with a lower surface of the second backside contact; and
forming a second backside power/signal line in contact with the second backside metal, the second backside power/signal line being configured to provide power or signal to the second S/D through the second backside metal, the second backside contact and the second SVC, or
both.

30. The method of claim 24,
wherein the backside contact is in contact with lower surfaces of the first and second S/Ds and a lower surface of the DW,
wherein the frontside contact is in contact with upper surfaces of the first S/D and the SVC, and
wherein the method further comprises:
forming a frontside metal in contact with an upper surface of the frontside contact; and
forming a frontside power/signal line in contact with the frontside metal, the frontside power/signal line being configured to provide power or signal to the first and second S/Ds through the frontside metal, the frontside contact, the SVC, and the backside contact.
